(19) United States
(12) Patent Application Publication
(10) Pub. No.: US 2021/0336222 A1
(43) Pub. Date: Oct. 28, 2021

(54) DISPLAY PANEL AND MANUFACTURING METHOD THEREOF

(71) Applicant: TCL China Star Optoelectronics Technology Co., Ltd., Shenzhen (CN)

(72) Inventor: Jiangjiang SONG, Shenzhen (CN)

(73) Assignee: TCL China Star Optoelectronics Technology Co., Ltd., Shenzhen (CN)

(21) Appl. No.: 16/627,824

(22) PCT Filed: Dec. 27, 2019
(86) PCT No.: PCT/CN2019/128930

§ 371 Date: Dec. 31, 2019

(30) Foreign Application Priority Data
Jun. 4, 2019 (CN) 201910479326.X

(51) Int. Cl. H01L 51/52; H01L 51/56

(52) U.S. Cl. CPC H01L 51/5268; H01L 51/5246; H01L 51/56; H01L 51/5259

(57) ABSTRACT

A display panel and a method for manufacturing the same are provided. The display panel includes a substrate; a light-emitting device disposed on the substrate; a scattering layer disposed on the light-emitting device, wherein a plurality of scattering particles are arranged in the scattering layer, the scattering particles are used to improve a luminous efficiency of the light-emitting device; a sealant arranged on the substrate and arranged around the light-emitting device and the scattering layer; and a cover plate disposed on the scattering layer and the sealant.

### FIELD OF INVENTION

The present application relates to the field of display technologies, and in particular, to a display panel and a manufacturing method thereof.

### BACKGROUND OF INVENTION

Organic light-emitting diodes (OLEDs) are widely used in display panels due to characteristics of low start-up voltage, light weight and thinness, and self-luminous to meet the needs of low energy consumption, light weight and thinness, and planar light sources.

However, the light outputting efficiency of the OLED display panels is generally not high. This is mainly because that when light is incident on an interface between an OLED device and a cover plate at an angle greater than a total reflection angle, the total reflection of the light will occur, which reduces the luminous efficiency of the OLED device.

### SUMMARY OF INVENTION

### Technical Problem

The present application mainly solves the technical problem that when light is incident on an interface between an OLED device and a cover plate at an angle greater than a total reflection angle, the total reflection of the light will occur and reduces the luminous efficiency of the OLED device.

### Technical Solutions

In a first aspect, the present application provides a display panel, including:

a substrate;

a light-emitting device disposed on the substrate;

a scattering layer disposed on the light-emitting device, wherein a plurality of scattering particles are arranged in the scattering layer, the scattering particles are used to improve a luminous efficiency of the light-emitting device;

a sealant arranged on the substrate and arranged around the light-emitting device and the scattering layer; and

a cover plate disposed on the scattering layer and the sealant;

wherein material of the scattering particles includes titanium dioxide and a magnetic material, and the scattering particles are a core-shell structure, the core-shell structure includes a core and a shell covering the core, and material of the shell includes titanium dioxide.

In the display panel provided in the present application, the scattering layer includes a liquid desiccant, and the scattering particles are arranged in the liquid desiccant and are close to a side of the cover plate.

In the display panel provided in the present application, the scattering particles are distributed in an array.

In the display panel provided in the present application, the substrate includes a center region and an edge region surrounding the center region; and

number of the scattering particles per unit area correspondingly provided on the edge region is greater than number of the scattering particles per unit area correspondingly provided on the center region.

In the display panel provided in the present application, the scattering particles include a plurality of first scattering particles and a plurality of second scattering particles, the first scattering particles are correspondingly disposed on the center region, and the second scattering particles are correspondingly disposed in the edge region; and

the first scattering particles are arranged at intervals, the second scattering particles are arranged at intervals, and the second scattering particles are surrounded the first scattering particles.

In a second aspect, the present application provides a display panel, including:

a substrate;

a light-emitting device disposed on the substrate;

a scattering layer disposed on the light-emitting device, wherein a plurality of scattering particles are arranged in the scattering layer, the scattering particles are used to improve a luminous efficiency of the light-emitting device;

a sealant arranged on the substrate and arranged around the light-emitting device and the scattering layer; and

a cover plate disposed on the scattering layer and the sealant.

In the display panel provided in the present application, the scattering layer includes a liquid desiccant, and the scattering particles are disposed in the liquid desiccant and are close to a side of the cover plate.

In the display panel provided in the present application, the scattering particles are distributed in an array.

In the display panel provided in the present application, the substrate includes a center region and an edge region surrounding the center region; and

number of the scattering particles per unit area correspondingly provided on the edge region is greater than number of the scattering particles per unit area correspondingly provided on the center region.

In the display panel provided in the present application, the scattering particles include a plurality of first scattering particles and a plurality of second scattering particles, the first scattering particles are correspondingly disposed on the center region, and the second scattering particles are correspondingly disposed on the edge region; and

the first scattering particles are arranged at intervals, the second scattering particles are arranged at intervals, and the second scattering particles are surrounded the first scattering particles.

In the display panel provided in the present application, material of the scattering particles includes titanium dioxide and a magnetic material.

In the display panel provided in the present application, the scattering particles are a core-shell structure, the core-shell structure includes a core and a shell covering the core; and

wherein material of the core is a magnetic material, and material of the shell is titanium dioxide.

In a third aspect, the present application provides a method for manufacturing a display panel, including:

providing a substrate, wherein the substrate includes a first region and a second region surrounding the first region;

forming a light-emitting device on the first region and a sealant on the second region;

coating a previously prepared mixed solution to a surface of the light-emitting device, wherein the mixed solution includes a plurality of scattering particles, the scattering particles are used to improve a light-extraction efficiency of the light-emitting device;

attaching a cover plate to the sealant; and

curing the sealant and the mixed solution to form a scattering layer on the light-emitting device.

In the method for manufacturing the display panel provided in the present application, before attaching a cover plate to the sealant, after coating a previously prepared mixed solution to a surface of the light-emitting device, the manufacturing method further includes:

processing the mixed solution to move the scattering particles of the mixed solution to a preset position.

In the method for manufacturing the display panel provided in the present application, processing the mixed solution to move the scattering particles of the mixed solution to a preset position includes:

placing the substrate in a magnetic field; and

processing the mixed solution by using the magnetic field to move the scattering particles of the mixed solution to the preset position.

### BENEFICIAL EFFECT

The beneficial effect of the present application is that the luminous efficiency of the light-emitting device can be improved.

### BRIEF DESCRIPTION OF FIGURES

In order to illustrate the technical solutions of the present disclosure or the related art in a clearer manner, the drawings desired for the present disclosure or the related art will be described hereinafter briefly. Obviously, the following drawings merely relate to some embodiments of the present disclosure, and based on these drawings, a person skilled in the art may obtain the other drawings without any creative effort.

FIG. 1 is a schematic structural diagram of a first embodiment of a display panel provided by the present application.

FIG. 2 is a schematic plane view of the first embodiment of the display panel shown in FIG. 1.

FIG. 3 is a schematic plane view of a second embodiment of the display panel shown in FIG. 1.

FIG. 4 is a schematic structural diagram of a scattering particle provided by the present application.

FIG. 5 is a schematic flowchart of a method for manufacturing a display panel provided by the present application.

### DETAILED DESCRIPTION OF EMBODIMENTS

The embodiments of the present application are described in detail below, and examples of the embodiments are shown in the drawings, wherein the same or similar reference numerals indicate the same or similar elements or elements having the same or similar functions throughout. The embodiments described below with reference to the drawings are exemplary and are only used to explain the present application, and should not be construed as limiting the present application.

Please refer to FIG. 1, which is a schematic structural diagram of a first embodiment of a display panel provided by the present application. The present application provides a display panel 1 including a substrate 10, a light-emitting device 20, a scattering layer 30, a sealant 40, and a cover plate 50. The light-emitting device 20 is disposed on the substrate 10, the scattering layer 30 is disposed on the light-emitting device 20, and a plurality of scattering particles 60 are disposed in the scattering layer 30. The scattering particles 60 are used to improve the luminous efficiency of the light-emitting device. The sealant 40 is arranged on the substrate 10 and is arranged around the light-emitting device 20 and the scattering layer 30. The cover plate is disposed on the scattering layer 30 and the sealant 40.

The substrate 10 can be a flexible substrate or a rigid substrate. The light-emitting device 20 can include various circuit structures according to actual needs. The scattering layer 30 is disposed on a surface of the light-emitting device 20 in a light outputting direction. The sealant 40 can be an ultraviolet curing adhesive. The plurality of scattering particles 60 are arranged in the scattering layer 30. The light emitted from the light-emitting device 20 passes through the scattering layer 30, the scattering particles 60 will refract the light emitted from the light-emitting device 20 to reduce the total reflection occurring between the cover plate 30 and the device 20 caused by the light emitted from the light-emitting device 20, thereby further improving the luminous efficiency of the light-emitting device 20.

In some embodiments, the scattering layer 30 includes a liquid desiccant, and the plurality of scattering particles 60 are disposed in the liquid desiccant and are close to a side of the cover plate 50. The liquid desiccant can be an epoxy resin. In addition, it should be noted that the scattering layer 30 is set as a liquid desiccant, and the plurality of scattering particles 60 are close to the side of the cover plate 50, which can further reduce the total reflection occurring between the cover plate 30 and the device 20 caused by the light emitted from the light-emitting device 20, thereby further improving the luminous efficiency of the light-emitting device 20. In addition, the scattering layer 30 can also be used to absorb water and oxygen to prevent water and oxygen from entering the light-emitting device 20 and cause the light-emitting device 20 to fail. Therefore, product yield of the display panel 1 is improved.

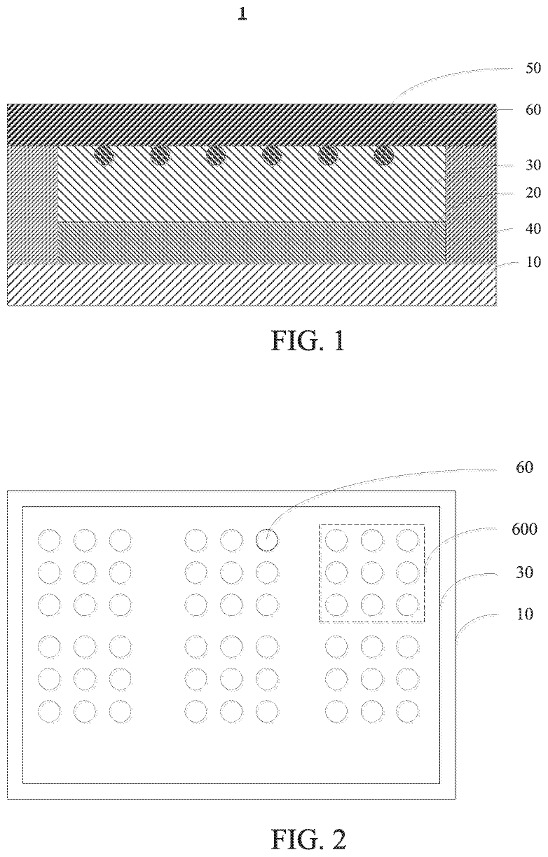

An arrangement of the plurality of scattering particles 60 can be determined according to an arrangement of pixels in the display panel 1. For example, in the display panel 1, a plurality of pixels are distributed in an array, and a plurality of scattering particles 60 can form a plurality of scattering particle sets 600 distributed in an array. Each scattering particle set 600 includes a plurality of scattering particles 60 distributed in an array, and each scattering particle set 600 corresponds to a pixel, that is, in some embodiments, a plurality of scattering particles 60 are distributed in an array, as shown in FIG. 2.

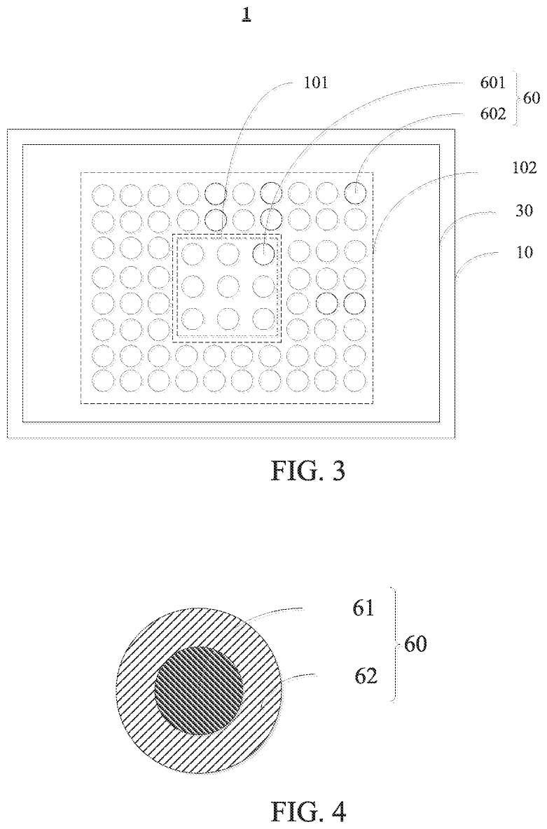

In some embodiments, please refer to FIG. 3, which is a schematic plane view of a second embodiment of the display panel shown in FIG. 1. The present application further provides a display panel 1. The display panel 1 of FIG. 3 differs from the display panel 1 of FIG. 2 in that the substrate 10 includes a central region 101 and an edge region 102 surrounding the central region 101. The number of the scattering particles 60 per unit area correspondingly provided on the edge region 102 is greater than the number of the scattering particles 60 per unit area correspondingly provided on the center region 101. For a general display panel, the brightness of the center region is greater than the brightness of the peripheral region, that is, the brightness of the center region 101 is greater than the brightness of the edge region 102. In order to improve the luminescence uniformity of display panel 1, the density of scattering particles 60 on the edge region 102 can be set to be greater than the density of scattering particles 60 on the center region 101. Here, the density refers to the number per unit area, that is, the number of the scattering particles 60 per unit area correspondingly provided on the edge region 102 is greater than the number of the scattering particles 60 per unit area correspondingly provided on the center region 101.

Furthermore, please continue referring to FIG. 3, the scattering particles 60 include a plurality of first scattering particles 601 and a plurality of second scattering particles 602, the first scattering particles 601 are correspondingly disposed on the center region 101, and the second scattering particles 602 are correspondingly disposed on the edge region 102. The first scattering particles 601 are arranged at intervals, the plurality of second scattering particles 602 are arranged at intervals, and the second scattering particles 601 are surrounded the first scattering particles 601.

Please refer to FIG. 4, which is a schematic structural diagram of a scattering particle provided by the present application. The material of the scattering particles 60 includes titanium dioxide and a magnetic material. Furthermore, a structure of the scattering particles 60 is a core-shell structure, and the core-shell structure includes a core 61 and a shell 62 covering the core 61. The material of the core 61 is a magnetic material, and the material of the shell 62 is titanium dioxide.

By covering the titanium dioxide shell 62 on the magnetic core 61 and using the liquid desiccant as the main material of the scattering layer 30. The position of the scattering particles 60 in the scattering layer 30 can be controlled according to the actual situation, and the light emitted from the light-emitting device 20 passes through the scattering layer 30, these scattering particles 60 will refract the light emitted from the light-emitting device 20, so as to reduce the total reflection occurring between the cover plate 30 and the device 20 caused by the light emitted from the light-emitting device 20, thereby further improving the luminous efficiency of the light-emitting device 20.

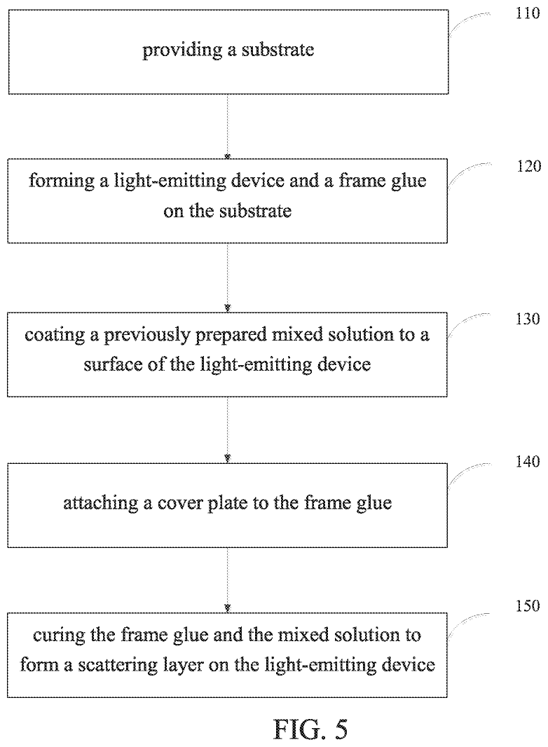

Correspondingly, please refer to FIG. 5, which is a schematic flowchart of a method for manufacturing a display panel provided by the present application. The present application provides a method for manufacturing a display panel, including:

110, providing a substrate.

The substrate can be a flexible substrate or a rigid substrate. For example, the substrate is a rigid substrate.

120, forming a light-emitting device and a sealant on the substrate.

The light-emitting device and the sealant are formed on a predetermined region of the substrate. The sealant is disposed around the light-emitting device, and a height of the sealant to the substrate is greater than a height of the light-emitting device to the substrate. The light-emitting device can include an anode, an organic luminescent layer, a cathode, and the like.

130, coating a previously prepared mixed solution to a surface of the light-emitting device.

The mixed solution includes a plurality of scattering particles, the scattering particles are used to improve a light-extraction efficiency of the light-emitting device. For the structure of the scattering particles, please refer to the previous embodiment. In actual production, the mixed solution is dripped on the light-emitting device. Since the sealant is disposed around the light-emitting device, the sealant can play a limiting role. In order to further reduce the total reflection occurring between the cover plate and the device caused by the light emitted from the light-emitting device, after the dripping of the mixed solution is completed, the position of the scattering particles can also be adjusted, that is, in some embodiments, before attaching a cover plate to a sealant, after coating a previously prepared mixed solution to a surface of the light-emitting device, the manufacturing method further includes: processing the mixed solution to move the scattering particles of the mixed solution to a preset position. For example, the scattering particles have a core-shell structure with titanium dioxide as the shell and a magnetic material as the core. Therefore, the position of the scattering particles in the scattering layer can be adjusted by a magnetic field, that is, in some embodiments, processing the mixed solution to move the scattering particles of the mixed solution to a preset position includes:

placing the substrate in a magnetic field;

processing the mixed solution by using the magnetic field to move the scattering particles of the mixed solution to the preset position.

140, attaching a cover plate to the sealant.

The attaching manner can be in a hard-to-hard or soft-to-hard manner, specifically according to the actual situation.

150, curing the sealant and the mixed solution to form a scattering layer on the light-emitting device.

The UV curing method is used to cure the sealant and the mixed solution, so that the mixed solution is cured on the light-emitting device to form a scattering layer. It should be noted that a thickness of the scattering layer and a particle diameter of the scattering particles in the scattering layer are different, so that the light-extraction efficiency is different, please refer to table 1 for details.

TABLE 1

| | Scattering | Particle | |
|---|---|---|---|
| | layer | diameter in the | |
| | thickness/ | scattering layer/ | Light-extraction |
| | micron | micron | efficiency/percent |
| Experimental | 15 | 8 | 28 |
| group 1 | | | |
| Experimental | 20 | 8 | 18 |
| group 2 | | | |
| Experimental | 5 | 7 | 15 |
| group 3 | | | |
| Experimental | 8 | 8 | 10 |
| group 4 | | | |
| Experimental | 10 | 12 | 11 |
| group 5 | | | |
| Experimental | 12 | 10 | 11 |
| group 6 | | | |
| Experimental | 12 | 10 | 9 |
| group 7 | | | |
| Control group | | | 3 |

It should be noted that the control group in Table 1 is a conventional display panel, that is, a display panel without scattering particles.

The present application provides a method for manufacturing a display panel, which includes providing a substrate, forming a light-emitting device and a sealant on the substrate, coating a previously prepared mixed solution to a surface of the light-emitting device, attaching a cover plate to the sealant, and curing the sealant and the mixed solution to form a scattering layer on the light-emitting device. In the present application, a plurality of scattering particles are arranged in the scattering layer, and the scattering particles will refract the light emitted from the light-emitting device, so as to reduce the total reflection occurring between the cover plate and the device caused by the light emitted from the light-emitting device, thereby further improving the luminous efficiency of the light-emitting device.

The display panel and the manufacturing method thereof provided in the embodiments of the present application are described in detail above. Embodiments of the present invention have been described, but not intended to impose any unduly constraint to the appended claims. For a person skilled in the art, any modification of equivalent structure or equivalent process made according to the disclosure and drawings of the present invention, or any application thereof, directly or indirectly, to other related fields of technique, is considered encompassed in the scope of protection defined by the claims of the present invention.

What is claimed is:

1. A display panel, comprising:
a substrate;
a light-emitting device disposed on the substrate;
a scattering layer disposed on the light-emitting device, wherein a plurality of scattering particles are arranged in the scattering layer, the scattering particles are used to improve a luminous efficiency of the light-emitting device;
a sealant arranged on the substrate and arranged around the light-emitting device and the scattering layer; and
a cover plate disposed on the scattering layer and the sealant;
wherein material of the scattering particles comprises titanium dioxide and a magnetic material, and the scattering particles are a core-shell structure, the core-shell structure comprises a core and a shell covering the core, and material of the shell comprises titanium dioxide.

2. The display panel according to claim 1, wherein the scattering layer comprises a liquid desiccant, and the scattering particles are arranged in the liquid desiccant and are close to a side of the cover plate.

3. The display panel according to claim 2, wherein the scattering particles are distributed in an array.

4. The display panel according to claim 3, wherein the substrate comprises a center region and an edge region surrounding the center region; and
number of the scattering particles per unit area correspondingly provided on the edge region is greater than number of the scattering particles per unit area correspondingly provided on the center region.

5. The display panel according to claim 4, wherein the scattering particles comprise a plurality of first scattering particles and a plurality of second scattering particles, the first scattering particles are correspondingly disposed on the center region, and the second scattering particles are correspondingly disposed in the edge region; and
the first scattering particles are arranged at intervals, the second scattering particles are arranged at intervals, and the second scattering particles are surrounded the first scattering particles.

6. A display panel, comprising:
a substrate;
a light-emitting device disposed on the substrate;
a scattering layer disposed on the light-emitting device, wherein a plurality of scattering particles are arranged in the scattering layer, the scattering particles are used to improve a luminous efficiency of the light-emitting device;
a sealant arranged on the substrate and arranged around the light-emitting device and the scattering layer; and
a cover plate disposed on the scattering layer and the sealant.

7. The display panel according to claim 6, wherein the scattering layer comprises a liquid desiccant, and the scattering particles are disposed in the liquid desiccant and are close to a side of the cover plate.

8. The display panel according to claim 7, wherein the scattering particles are distributed in an array.

9. The display panel according to claim 8, wherein the substrate comprises a center region and an edge region surrounding the center region; and
number of the scattering particles per unit area correspondingly provided on the edge region is greater than number of the scattering particles per unit area correspondingly provided on the center region.

10. The display panel according to claim 9, wherein the scattering particles comprise a plurality of first scattering particles and a plurality of second scattering particles, the first scattering particles are correspondingly disposed on the center region, and the second scattering particles are correspondingly disposed on the edge region; and
the first scattering particles are arranged at intervals, the second scattering particles are arranged at intervals, and the second scattering particles are surrounded the first scattering particles.

11. The display panel according to claim 6, wherein material of the scattering particles comprises titanium dioxide and a magnetic material.

12. The display panel according to claim 11, wherein the scattering particles are a core-shell structure, the core-shell structure comprises a core and a shell covering the core; and
wherein material of the core is a magnetic material, and material of the shell is titanium dioxide.

13. A method for manufacturing a display panel, comprising:
providing a substrate;
forming a light-emitting device and a sealant on the substrate;
coating a previously prepared mixed solution to a surface of the light-emitting device, wherein the mixed solution comprises a plurality of scattering particles, the scattering particles are used to improve a light-extraction efficiency of the light-emitting device;
attaching a cover plate to the sealant; and
curing the sealant and the mixed solution to form a scattering layer on the light-emitting device.

14. The manufacturing method according to claim 13, wherein before attaching a cover plate to the sealant, after coating a previously prepared mixed solution to a surface of the light-emitting device, the manufacturing method further comprises:
processing the mixed solution to move the scattering particles of the mixed solution to a preset position.

15. The manufacturing method according to claim 14, wherein processing the mixed solution to move the scattering particles of the mixed solution to a preset position comprises:
placing the substrate in a magnetic field; and
processing the mixed solution by using the magnetic field to move the scattering particles of the mixed solution to the preset position.
